(19) United States
(12) Patent Application Publication
(10) Pub. No.: US 2025/0221100 A1
(43) Pub. Date: Jul. 3, 2025

(54) LIGHT EMITTING DIODE STRUCTURE

(71) Applicant: Taiwan-Asia Semiconductor Corporation, Hsinchu City (TW)

(72) Inventor: Kun-De Lin, Hsinchu City (TW)

(21) Appl. No.: 18/770,301

(22) Filed: Jul. 11, 2024

(30) Foreign Application Priority Data
Dec. 29, 2023 (TW) 112151698

(51) Int. Cl. H01L 33/22; H01L 33/10

(52) U.S. Cl. CPC H10H 20/82; H10H 20/814

(57) ABSTRACT

A light emitting diode structure is provided. The light emitting diode includes a permanent substrate, a bonding metal composite layer, a mirror composite layer and an epitaxial semiconductor composite layer. The bonding metal composite layer is disposed on the permanent substrate, the mirror composite layer is disposed on the bonding metal composite layer, and the epitaxial semiconductor composite layer is disposed on the mirror reflection composite layer. There is a non-flat surface between the bonding metal composite layer and the permanent substrate, and the surface roughness (Ra) of the non-flat surface is less than 0.5 microns (μm).

### CROSS-REFERENCES TO RELATED APPLICATIONS

This application claims the benefit of priority to Taiwanese Patent Application No. 112151698 filed on Dec. 29, 2023, which is hereby incorporated by reference in its entirety.

### BACKGROUND OF THE INVENTION

### Field of the Invention

The present invention relates to a light emitting diode structure, in particular to a light emitting diode structure with high brightness.

### Descriptions of the Related Art

A light emitting diode (LED) structure has the advantages of high brightness, small size, low power consumption and long life, and is widely used in lighting or display products. Wafer bonding in the light emitting diode manufacturing process is a key step of bonding a single LED chip to a carrier substrate. The purpose of this bonding process is to improve light output efficiency and heat dissipation management for enhancing LED chip performance.

Specifically, by transferring the LED wafer that has completed the semiconductor epitaxial process to a permanent substrate through metal bonding, the light output can be managed more effectively. The substrate may contain some optical components, such as mirror reflection layers, which help to improve the reflection effect of light and increase the light extraction efficiency. At the same time, by bonding with a substrate with good heat dissipation efficiency, the LED chip and the cooling substrate are closely combined, which is helpful to effectively transfer the heat generated by the LED chip to the outside through the substrate. Thereby, the appropriate operating temperature of the LED chip will be kept and the LED chip performance and lifespan will be improved accordingly.

However, during the bonding process of the LED chip and the permanent substrate, the mirror reflection system already existed on the LED chip may be affected and thus worsen the performance of the LED. In the conventional metal bonding process, in order to ensure the reflection efficiency of the mirror reflection system of the LED chip, it is necessary to ensure that the bonding surface between the LED chip and the permanent substrate remains flat. If the bonding surface is not flat after the bonding process, the flatness of the mirror reflection system will be affected accordingly. And eventually, some of the light generated by the LED chips will be scattered during reflection and the reflection efficiency will be decreased. The light extraction efficiency will be ultimately reduced as well. In order to overcome the above-mentioned problems that the metal bonding process affects the light extraction of the LED chip, the industry urgently needs an innovative light emitting diode structure that can balance the bonding strength between the LED chip and the permanent substrate while improving the performance of the LED chip.

### SUMMARY OF THE INVENTION

The main objective of the present invention is to provide a light emitting diode structure with high brightness which can enhance the metal bonding strength without worsening the reflection efficiency of the mirror reflection system by adjusting the roughness of the interface between the permanent substrate and the metal bonding layer. The yield of the metal bonding process in the conventional light emitting diode structure and the light extraction efficiency can be improved accordingly.

To achieve the above objective, the present invention discloses a light emitting diode structure. The light emitting diode structure includes a permanent substrate, a bonding metal composite layer, a mirror composite layer and an epitaxial semiconductor composite layer. The bonding metal composite layer is disposed on the permanent substrate, the mirror reflection composite layer is disposed on the bonding metal composite layer, and the epitaxial semiconductor composite layer is disposed on the mirror reflection composite layer. The interface between the bonding metal composite layer and the permanent substrate is a non-flat surface, and the surface roughness (Ra) of the non-flat surface is less than 0.5 micrometers (μm).

In one embodiment of the light emitting diode structure of the present invention, the bonding metal composite layer includes a first bonding metal layer and a second bonding metal layer, and the interface between the first bonding metal layer and the second bonding metal layer is a flat surface.

In one embodiment of the light emitting diode structure of the present invention, a material of the first bonding metal layer and the second bonding metal layer is selected from a group consisting of gold (Au), indium (In), tin (Sn) and their combinations.

In one embodiment of the light emitting diode structure of the present invention, a thickness of the first bonding metal layer and the second bonding metal layer ranges from 1 micrometer to 2 micrometers.

In one embodiment of the light emitting diode structure of the present invention, an interface between the bonding metal composite layer and the permanent substrate is a patterned surface, and a patterned depth of the patterned surface is less than 0.5 micrometers.

In one embodiment of the light emitting diode structure of the present invention, the mirror reflection composite layer includes a first mirror reflection layer and a second mirror reflection layer, and an interface between the first mirror reflection layer and the second mirror reflection layer is a flat surface.

In one embodiment of the light emitting diode structure of the present invention, a material of the first mirror reflection layer is selected from a group consisting of titanium dioxide (TiO2), silicon nitride (SiNₓ), silicon dioxide (SiO₂), magnesium fluoride (MgF₂), indium tin oxide (ITO), indium zinc oxide (IZO), indium gallium zinc oxide (IGZO), zinc oxide (ZnO) and their combinations.

In one embodiment of the light emitting diode structure of the present invention, a material of the second mirror reflection layer is selected from a group consisting of silver (Ag), gold (Au), aluminum (Al), platinum (Pt), titanium (Ti), nickel (Ni) and their combinations.

To achieve the above objective, the present invention discloses a light emitting diode structure. The light emitting diode structure includes a permanent substrate, a bonding metal composite layer, a mirror composite layer and an epitaxial semiconductor composite layer. The bonding metal composite layer is disposed on the permanent substrate, the mirror reflection composite layer is disposed on the bonding metal composite layer, and the epitaxial semiconductor composite layer is disposed on the mirror reflection composite layer. The interface between the mirror reflection composite layer and the epitaxial semiconductor composite layer is a non-flat surface. The mirror reflection composite layer includes a first mirror reflection layer and a second mirror reflection layer. The interface between the first mirror reflection layer and the second mirror reflection layer is a flat surface.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic view showing a light emitting diode structure in one embodiment of the present invention;

FIG. 2 is a schematic view showing a light emitting diode structure in another embodiment of the present invention; and

FIG. 3 is a schematic view showing a light emitting diode structure in another embodiment of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

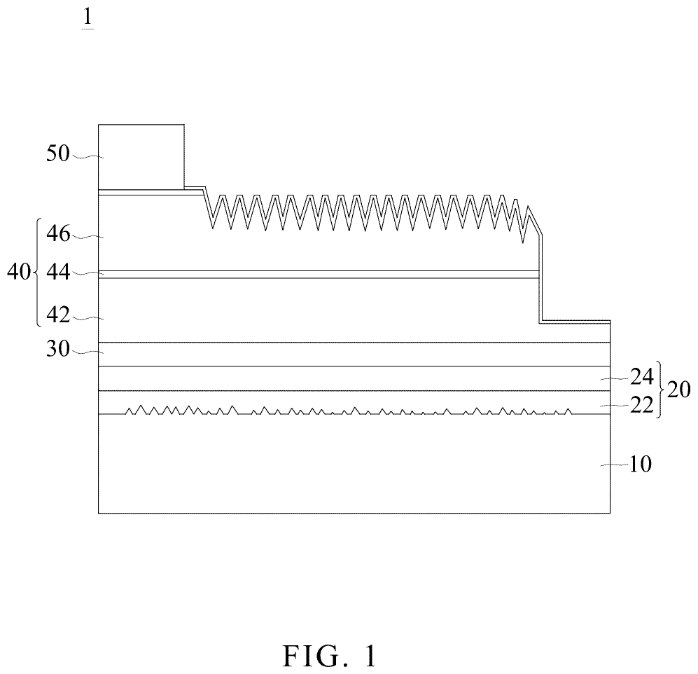

Please refer to FIG. 1, which discloses one embodiment of the light emitting diode structure of the present invention. The light emitting diode structure 1 includes a permanent substrate 10, a bonding metal composite layer 20, a mirror reflection composite layer 30, an epitaxial semiconductor composite layer 40, and an electrode 50. The bonding metal composite layer 20 is disposed on the permanent substrate 10, the mirror reflection composite layer 30 is disposed on the bonding metal composite layer 20, the epitaxial semiconductor composite layer 40 is disposed on the mirror reflection composite layer 30, and the electrode 50 is disposed on the epitaxial semiconductor composite layer 40. It should be noted that the light emitting diode structure of the present invention shown in FIG. 1 has transferred the completed epitaxial composite layer from a temporary epitaxial growth substrate to a permanent substrate using the innovative technology of the present invention. Several embodiments of the present invention will be described in detail below.

Specifically, the permanent substrate 10 of the light emitting diode structure 1 of the present invention can be, but is not limited to, a silicon substrate or a sapphire substrate, and an appropriate substrate can be selected according to the requirements of the actual application and the characteristics of the manufacturing process. For example, a silicon substrate provides better mechanical structural support strength, which contributes to stability during the manufacturing process. Additionally, the heat dissipation effect of a silicon substrate is better than that of a sapphire substrate, helping to control the temperature of the LED chip. Moreover, silicon substrates are relatively lower in cost compared to sapphire substrates, which is an important factor in industrial production. On the other hand, sapphire substrates have high transparency to blue and ultraviolet light, which helps to improve the light extraction efficiency of LED chips. Furthermore, sapphire substrates exhibit better stability at high temperatures, which is important for high-power LED chip applications. Additionally, sapphire is a better insulator, helping to prevent current penetration and improve the insulation performance of lighting devices.

Furthermore, in one embodiment of the light emitting diode structure of the present invention, the epitaxial semiconductor composite layer 40 above the permanent substrate 10 can be, but is not limited to, an aluminum gallium indium arsenide (AlGaInAs) double heterostructure. The epitaxial semiconductor composite layer 40 is originally grown on an epitaxial growth substrate (not shown), such as indium phosphide (InP) substrate. Specifically, in this embodiment, the double heterostructure of the epitaxial semiconductor composite layer 40 includes a P-type epitaxial semiconductor layer 42, an active layer 44, and an N-type epitaxial semiconductor layer 46. The P-type epitaxial semiconductor layer 42 is a carbon (C)-doped aluminum gallium arsenide (AlGaAs) confinement layer. The active layer 44 forms a multiple quantum well (MQW) structure, which includes aluminum gallium arsenide (AlGaAs) as barrier layers of the multiple quantum well and indium gallium arsenide (InGaAs) as the well layer. Additionally, the N-type epitaxial semiconductor layer 46 is a silicon (Si)-doped aluminum gallium arsenide (AlGaAs) confinement layer. It should be noted that the materials described in the above embodiment are merely exemplary, and the present invention is not limited thereto. In practical applications, materials and their compositions can be adjusted according to the emission wavelength. For example, the epitaxial layers may be aluminum gallium indium phosphide (AlGaInP), indium gallium phosphide (InGaP), aluminum gallium arsenide (AlGaAs), indium gallium arsenide (InGaAs), indium phosphide (InP), and so on.

Next, in this embodiment, the mirror reflection composite layer 30 comprises a first mirror reflection layer 32 and a second mirror reflection layer 34. The first mirror reflection layer 32 may be, but not limited to, composed of low refractive index dielectric materials selected from a group consisting of titanium dioxide (TiO₂), silicon nitride (SiNₓ), silicon dioxide (SiO₂), magnesium fluoride (MgF₂), indium tin oxide (ITO), indium zinc oxide (IZO), indium gallium zinc oxide (IGZO), zinc oxide (ZnO), and their combinations. The second mirror reflection layer 34 may be, but not limited to, composed of high reflectivity metal materials selected from a group consisting of silver (Ag), gold (Au), aluminum (Al), platinum (Pt), titanium (Ti), nickel (Ni), and their combinations.

In one embodiment of the present invention, considering factors such as the support strength and thermal efficiency of the light emitting diode structure, the epitaxial semiconductor composite layer 40 in the above-mentioned light emitting diode structure must be transferred from the original epitaxial growth substrate to the silicon-based permanent substrate 10 using a metal bonding process, and then the original epitaxial growth substrate is removed. Therefore, before the metal bonding process, a first bonding metal layer 22 is formed on the permanent substrate 10 using a metal evaporation method. Subsequently, a second bonding metal layer 24 is formed above the mirror reflection composite layer 30 of the original epitaxial growth substrate using an evaporation method. The materials of the first bonding metal layer 22 and the second bonding metal layer 24 are selected from a group consisting of gold (Au), indium (In), tin (Sn), and their combinations. Moreover, the thickness of both the first bonding metal layer 22 and the second bonding metal layer 24 ranges approximately from 1 micrometer (μm) to 2 micrometers (μm).

As disclosed in the prior art mentioned above, when performing metal bonding between the permanent substrate, similarly, it is necessary to ensure that the bonding surfaces between the first bonding metal layer 22 and the second bonding metal layer 24 remain flat to ensure the reflection efficiency of the mirror reflection system and avoid a reduction in reflection efficiency due to uneven bonding surfaces. However, on the other hand, to increase the bonding strength between the first bonding metal layer 22 and the second bonding metal layer 24 and improve the process yield of metal bonding, the present invention designs a non-flat interface between the permanent substrate 10 and the first bonding metal layer 22. By introducing this non-flat interface, the bonding strength and process yield of the metal bonding process can be increased by increasing the bonding area, thereby facilitating the transfer of the epitaxial semiconductor structure to the permanent substrate. However, there should be an upper limit to the non-flatness between the permanent substrate 10 and the first bonding metal layer 22 to avoid excessive “roughness” between the bonding surfaces, which may indirectly affect the flatness of the mirror reflection composite layer 30 during metal bonding of the first and second bonding metal layers 22 and 24 for reducing the reflection efficiency of light. Specifically, according to the research of the present invention, the roughness Ra value of the non-flat interface between the permanent substrate 10 and the first bonding metal layer 22 must be less than 0.5 micrometers (μm) to ensure the flatness of the mirror reflection composite layer 30 and increase the bonding strength between the two bonding metal layers.

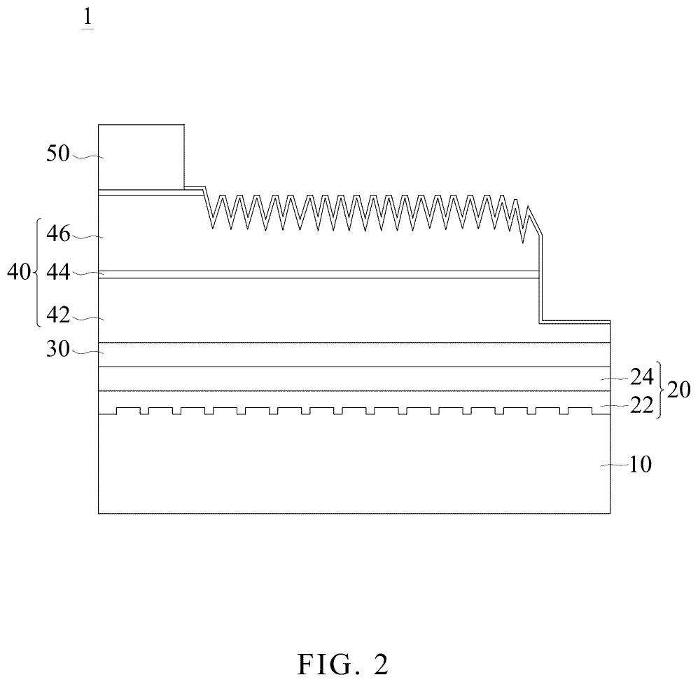

In another embodiment of the present invention, a patterned process can be employed to achieve the purpose of a non-flat interface between the bonding metal composite layer and the permanent substrate. Please refer to FIG. 2 for details. Specifically, after performing the patterned process, a patterned surface is formed between the first bonding metal layer 22 and the permanent substrate 10, and the patterned depth of the patterned surface must also be less than 0.5 micrometers (μm). This ensures the flatness of the mirror reflection composite layer 30 while enhancing the bonding strength between the two bonding metal layers, thus avoiding a reduction in the reflection efficiency of the mirror layer.

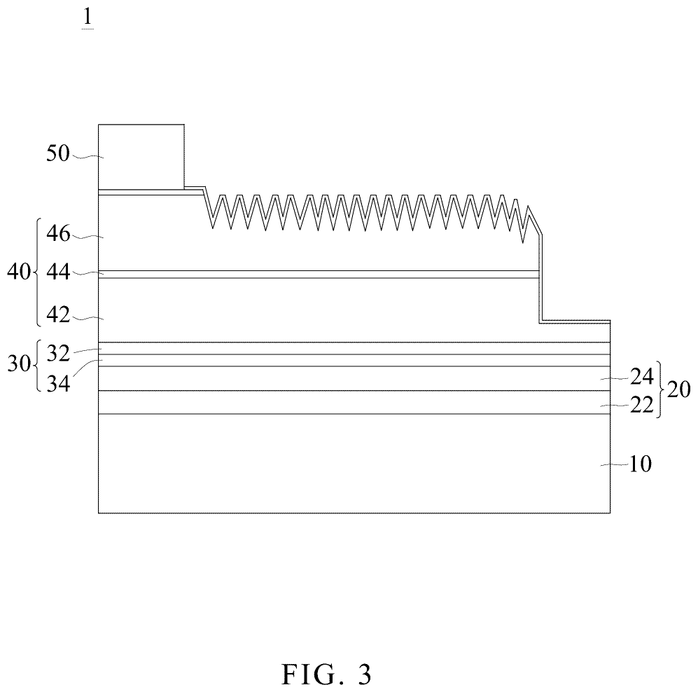

It should be noted that after completing the epitaxial process on the epitaxial semiconductor layer 40 on the epitaxial growth substrate, the surface of the epitaxial semiconductor layer 40 is typically non-flat with fluctuations in height. Therefore, when performing the thin film coating process for the mirror system on the epitaxial semiconductor layer 40, the first mirror reflection layer 32 in the mirror reflection composite layer 30 typically retains the non-flatness formed on the epitaxial semiconductor layer 40. This results in a non-flat interface between the first mirror reflection layer 32 and the epitaxial semiconductor layer 40 within the mirror reflection composite layer 30. In this case, if the metal coating process for the second mirror reflection layer 34 in the mirror reflection composite layer 30 is continued without any treatment, the interface between the first mirror reflection layer 32 and the second mirror reflection layer 34 will also be non-flat. This non-flat interface will reduce the reflection efficiency of the light emitted by the LED. Thereby, the light extraction efficiency of the LED will be downgraded. To avoid the above-mentioned problems, please refer to FIG. 3, where the present invention specifically performs a polishing process after completing the coating process for the first mirror reflection layer 32 and before carrying out the coating process for the second mirror reflection layer 34. This polishing process improves the flatness of the surface of the first mirror reflection layer 32, and then the coating process for the second mirror reflection layer 34 is carried out. Therefore, after completing the mirror coating process, the interface between the first mirror reflection layer 32 and the second mirror reflection layer 34 in the mirror reflection composite layer 30 of the present invention becomes flat. Thereby, the reflection efficiency of the mirror system will be enhanced and the light extraction efficiency of the LED will be increased accordingly.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A light emitting diode structure, including:
a permanent substrate;
a bonding metal composite layer, disposed on the permanent substrate;
a mirror reflection composite layer, disposed on the bonding metal composite layer; and
an epitaxial semiconductor composite layer, disposed on the mirror reflection composite layer;
wherein an interface between the bonding metal composite layer and the permanent substrate is a non-flat surface, and the surface roughness (Ra) of the non-flat surface is less than 0.5 micrometers (μm).

2. The light emitting diode structure of claim 1, wherein the bonding metal composite layer includes a first bonding metal layer and a second bonding metal layer, and an interface between the first bonding metal layer and the second bonding metal layer is a flat surface.

3. The light emitting diode structure of claim 2, wherein a material of the first bonding metal layer and the second bonding metal layer is selected from a group consisting of gold (Au), indium (In), tin (Sn) and their combinations.

4. The light emitting diode structure of claim 2, wherein a thickness of the first bonding metal layer and the second bonding metal layer ranges from 1 micrometer to 2 micrometers.

5. The light emitting diode structure of claim 1, wherein an interface between the bonding metal composite layer and the permanent substrate is a patterned surface, and a patterned depth of the patterned surface is less than 0.5 micrometers.

6. The light emitting diode structure of claim 1, wherein the mirror reflection composite layer includes a first mirror reflection layer and a second mirror reflection layer, and an interface between the first mirror reflection layer and the second mirror reflection layer is a flat surface.

7. The light emitting diode structure of claim 6, wherein a material of the first mirror reflection layer is selected from a group consisting of titanium dioxide (TiO2), silicon nitride (SiNₓ), silicon dioxide (SiO₂), magnesium fluoride (MgF₂), indium tin oxide (ITO), indium zinc oxide (IZO), indium gallium zinc oxide (IGZO), zinc oxide (ZnO) and their combinations.

8. The light emitting diode structure of claim 6, wherein a material of the second mirror reflection layer is selected from a group consisting of silver (Ag), gold (Au), aluminum (Al), platinum (Pt), titanium (Ti), nickel (Ni) and their combinations.

9. A light emitting diode structure, including:
a permanent substrate;
a bonding metal composite layer, disposed on the permanent substrate;
a mirror reflection composite layer, disposed on the bonding metal composite layer; and
an epitaxial semiconductor composite layer, disposed on the mirror reflection composite layer, and an interface between the mirror reflection composite layer and the epitaxial semiconductor composite layer is a non-flat surface;
wherein the mirror reflection composite layer includes a first mirror reflection layer and a second mirror reflection layer, and an interface between the first mirror reflection layer and the second mirror reflection layer is a flat surface.

10. The light emitting diode structure of claim 9, wherein a material of the first mirror reflection layer is selected from a group consisting of titanium dioxide (TiO₂), silicon nitride (SiNₓ), silicon dioxide (SiO₂), magnesium fluoride (MgF₂), indium tin oxide (ITO), indium zinc oxide (IZO), indium gallium zinc oxide (IGZO), zinc oxide (ZnO) and their combinations.

11. The light emitting diode structure of claim 9, wherein a material of the second mirror reflection layer is selected from a group consisting of silver (Ag), gold (Au), aluminum (Al), platinum (Pt), titanium (Ti), nickel (Ni) and their combinations.

12. The light emitting diode structure of claim 9, wherein an interface between the bonding metal composite layer and the permanent substrate is a non-flat surface, and the surface roughness (Ra) of the non-flat surface is less than 0.5 micrometers (μm).

13. The light emitting diode structure of claim 12, wherein the bonding metal composite layer further includes a first bonding metal layer and a second bonding metal layer, and an interface between the first bonding metal layer and the second bonding metal layer is a flat surface.

14. The light emitting diode structure of claim 13, wherein a material of the first bonding metal layer and the second bonding metal layer is selected from a group consisting of gold (Au), indium (In), tin (Sn) and their combinations.

15. The light emitting diode structure of claim 13, wherein a thickness of the first bonding metal layer and the second bonding metal layer ranges from 1 micrometer to 2 micrometers.

16. The light emitting diode structure of claim 9, wherein an interface between the bonding metal composite layer and the permanent substrate is a patterned surface, and a patterned depth of the patterned surface is less than 0.5 micrometers.
